(19) United States
(12) Patent Application Publication
(10) Pub. No.: US 2004/0132280 A1
(43) Pub. Date: Jul. 8, 2004

(54) Method of forming metal wiring in a semiconductor device

(75) Inventor: Se-Yeul Bae, Icheon-city (KR)

Correspondence Address: PILLSBURY WINTHROP, LLP, P.O. BOX 10500, MCLEAN, VA, 22102, US

(73) Assignee: Dongbu Electronics Co. Ltd., Seoul (KR)

(21) Appl. No.: 10/626,550

(22) Filed: Jul. 25, 2003

(30) Foreign Application Priority Data
Jul. 26, 2002 (KR) 10-2002-0044083
Jul. 23, 2003 (KR) 10-2003-0050647

(51) Int. Cl. H01L 21/4763

(52) U.S. Cl. 438/638; 438/631

(57) ABSTRACT

The present invention relates to a method of forming metal wiring in a semiconductor device, and the method includes forming a bottom metal pattern on a semiconductor substrate, forming an insulating layer on the semiconductor substrate including the bottom metal pattern, forming a first photoresist pattern for forming vial hole on the insulating layer, forming an unfinished via hole by removing the insulating layer selectively for a prescribed thickness using the first photoresist pattern as a mask, removing the first photoresist pattern, forming a second photoresist pattern for forming damascene pattern on the insulating layer around the unfinished via hole, forming a damascene pattern by removing the insulating layer selectively using the second photoresist pattern as a mask, removing the second photoresist pattern, and forming a metal wiring via damascene contact by filling metal in the damascene pattern. According to the present invention, semiconductor manufacturing yield is improved by preventing via hole defects during dual damascene process.

### BACKGROUND OF THE INVENTION

(a) Field of the Invention

The present invention relates to a method of forming metal wiring in a semiconductor device, and particularly to a method of forming metal wiring for preventing via hole defects during dual damascene process.

(b) Description of Related Art

Recently, a damascene process which is able to omit metal etching and insulator gap filling during wire forming process is suggested based on changes such as minute and multi-layered wiring due to the high operation speed and high integration of the semiconductor IC, introduction of copper and material having low dielectric constant to decrease RC signal delay, and difficulty of metal patterning due to decrease of design rule.

Now, a conventional dual damascene process of a semiconductor device is described with reference to FIGS. 1-4.

FIGS. 1-4 are sectional views illustrating process steps of a conventional method of forming metal wiring in a semiconductor device.

As shown in FIG. 1, a bottom metal pattern 13 is formed on a semiconductor substrate 11, a thick oxide layer 15 is deposited thereon, and a first photoresist pattern 17 which is a mask for forming via hole is formed on the oxide layer 15.

Next, as shown in FIG. 2, a via hole 19 exposing the metal pattern 13 thereunder is formed by etching the oxide layer 15 using the first photoresist pattern 17.

Subsequently, as shown in FIG. 3, a second photoresist pattern 21 which is a mask for forming damascene pattern is formed on the oxide layer 15 around the via hole 19.

Succeedingly, a damascene pattern (not shown) is formed by etching the oxide layer 15 selectively using the second photoresist pattern 21, and damascene contact 23 is formed by filling inside of the damascene pattern with metal.

According to the conventional method of forming metal wiring, the bottom metal pattern 13 exposed through the via hole 19 and sidewall of the via hole 19 get damaged by etching solution when the oxide layer 15 is etched to form the damascene pattern, which causes defects of via hole opening or void. In result, reliability of the device decreases.

To overcome the above shortcoming, a method of forming metal wiring, in which via holes are formed in the oxide layer using a mask for forming via holes, insides of the via holes are filled with a thick bottom anti-reflection layer applied thereon, and a damascene pattern is formed, is disclosed.

However, the above method using the bottom anti-reflection layer also has difficulties: process of filling the via holes with the bottom anti-reflection layer is not easy; and the bottom anti-reflection layer cannot serve as an etching barrier because etching selectivity between the bottom anti-reflection layer and the oxide layer is small.

### SUMMARY OF THE INVENTION

The present invention is devised to overcome the shortcomings of the above conventional method, and an aspect of the present invention is to provide a method of forming metal wiring in a semiconductor device which is able to increase manufacturing yield by preventing via hole defects during dual damascene process.

According to an embodiment of the present invention, a method of forming metal wiring, which includes forming a bottom metal pattern on a semiconductor substrate, forming an insulating layer on the semiconductor substrate including the bottom metal pattern, forming a first photoresist pattern for forming via hole on the insulating layer, forming an unfinished via hole by removing the insulating layer selectively for a prescribed thickness using the first photoresist pattern as a mask, removing the first photoresist pattern, forming a second photoresist pattern for forming damascene pattern on the insulating layer around the unfinished via hole, forming a damascene pattern by removing the insulating layer selectively using the second photoresist pattern as a mask, removing the second photoresist pattern, and forming a metal wiring via damascene contact by filling metal in the damascene pattern.

### BRIEF DESCRIPTION OF THE DRAWINGS

FIGS. 1-4 are sectional views illustrating process steps of a method of forming metal wiring in a semiconductor device using conventional damascene process; and

FIGS. 5-9 are sectional views illustrating process steps of a method of forming metal wiring in a semiconductor device using damascene process according to an embodiment of the present invention.

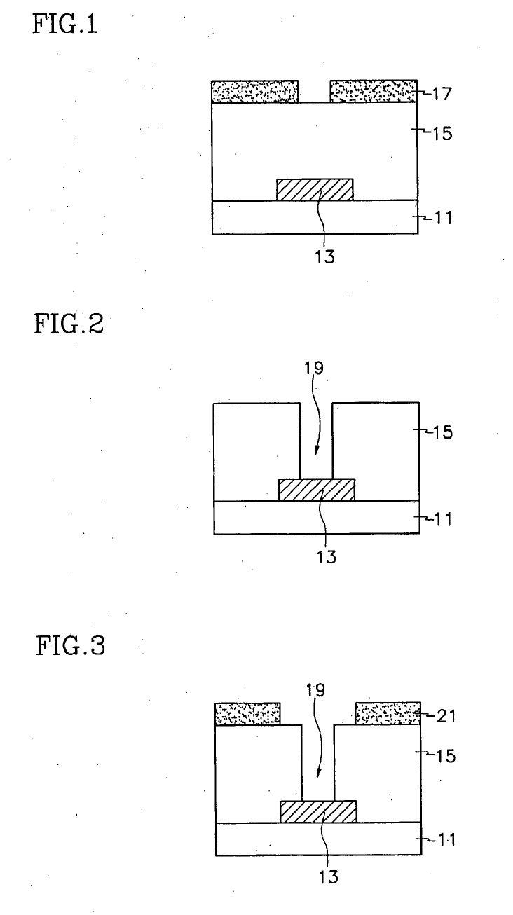

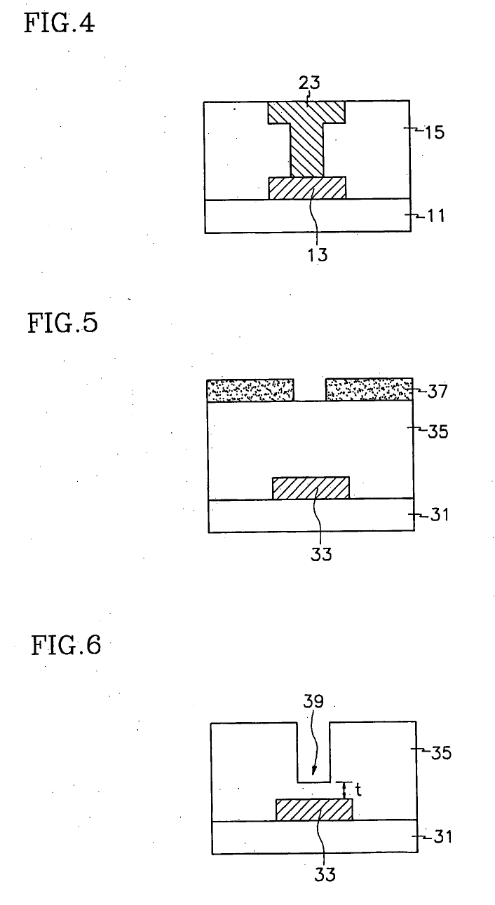

### DETAILED DESCRIPTION OF THE PREFERRED EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein.

FIGS. 5-9 are sectional views illustrating process steps of a method of forming metal wiring in a semiconductor device using damascene process according to an embodiment of the present invention.

According to a method of forming metal wiring in a semiconductor device according to an embodiment of the present invention, as shown in FIG. 5, a bottom metal pattern 33 is formed on a semiconductor substrate 31, a thick insulating layer 35 is deposited thereon, and a first photoresist pattern 37 which serves as a mask for forming via hole is formed on the insulating layer 35. An oxide formed in a furnace with a low temperature, preferably 150˜500° C., is used for the insulating layer 35.

Next, as shown in FIG. 6, the insulating layer 35 is selectively etched using the first photoresist pattern, which is a mask for forming via hole, to make the insulating layer 35 remain for a part t of its thickness to form unfinished via hole 39. The remaining thickness t of the insulating layer 35 when the unfinished via hole 39 is formed is preferably equal to or smaller than thickness t1 of an upper part of a metal damascene contact 45 shown in FIG. 9. The overall thickness of the insulating layer 35 might be adjusted in the range of 1,000˜20,000 Å as needed. After forming the unfinished via hole 39, the first photoresist pattern 37 is removed.

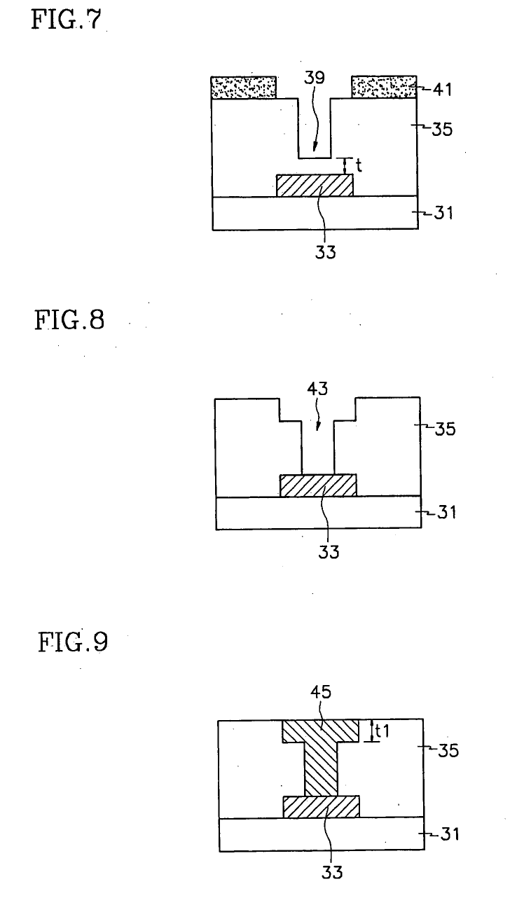

Subsequently, as shown in FIG. 7, a second photoresist pattern 41 which will be used as a mask for forming damascene pattern 43 is formed on the entire surface.

Succeedingly, as shown in FIG. 8, a damascene pattern is formed by etching the insulating layer for a thickness t1 of the upper part of the damascene contact 45 using the second photoresist pattern 21 for forming damascene pattern. Simultaneously, the remaining insulating layer of a prescribed thickness t inside the unfinished via hole 39 is etched to expose the bottom metal pattern 33. After forming the damascene pattern 43, the second photoresist pattern 41 is removed.

Finally, as shown in FIG. 9, a metal layer is deposited on the insulating layer 35 including the damascene pattern 43 and planarized by chemical mechanical polishing to form a metal wiring via damascene contact 45. A metal having good electric and deposition characteristics such as Cu, Al, W, Pt, Co, Ni, or alloy thereof is used for the metal wiring via damascene contact 45.

A single or multiple layer of refractory metal, nitride thereof, oxide thereof, or compound thereof might be formed between the damascene contact and the insulating layer as a diffusion barrier.

For depositing metal layer, electro-chemical deposition methods such as electroplating or electroless plating, chemical vapor deposition (CVD), or physical deposition (sputtering) may be used. When electrochemical deposition methods are used, a metal layer having similar chemical properties to the metal to be deposited may be deposited as seed metal.

Planarization of the metal and the insulating layer using CMP may be repeated if two or more wiring layers are formed.

According to the above description, when the insulating layer 35 is etched for a thickness t1 of the upper part of the damascene contact 45 to form the damascene pattern 33, the insulating layer of a prescribed thickness t remaining in the above unfinished via hole 39 is etched simultaneously.

According to the above embodiment, the bottom metal pattern is exposed through etching process for forming damascene pattern by forming the damascene pattern after the unfinished via hole is formed. Therefore, the bottom metal pattern is prevented from getting damaged during the etching process for forming damascene pattern, and damage of sidewall of the via hole can be minimized, thereby improving reliability of a semiconductor device and manufacturing yield.

While the present invention has been described in detail with reference to the preferred embodiments, it is to be understood that the invention is not limited to the disclosed embodiments, but, on the contrary, is intended to cover various modifications and equivalent arrangements included within the spirit and scope of the appended claims.

What is claimed is:

1. A method of forming metal wiring in a semiconductor device comprising:
forming a bottom metal pattern on a semiconductor substrate;
forming an insulating layer on the semiconductor substrate including the bottom metal pattern;
forming a first photoresist pattern for forming via hole on the insulating layer;
forming an unfinished via hole by removing the insulating layer selectively for a prescribed thickness using the first photoresist pattern as a mask;
removing the first photoresist pattern;
forming a second photoresist pattern for forming damascene pattern on the insulating layer around the unfinished via hole;
forming a damascene pattern by removing the insulating layer selectively using the second photoresist pattern as a mask;
removing the second photoresist pattern; and
forming a metal wiring via damascene contact by filling metal in the damascene pattern.

2. The method of claim 1, wherein a low temperature oxide is used for the insulating layer.

3. The method of claim 2, wherein the oxide is formed at the temperature of 150˜500° C.

4. The method of claim 1, wherein the unfinished via hole is formed to make the thickness of the insulating layer remaining inside the via hole equal to or less than the thickness of the upper part of damascene contact.

5. The method of claim 1, wherein the damascene contact is made of Cu, Al, W, Pt, Co, Ni, or alloy thereof.

6. The method of claim 1, wherein the damascene contact is formed by depositing metal on the insulating layer including the damascene pattern and planarizing the metal by CMP process.

7. The method of claim 6, wherein the metal is deposited by electrochemical deposition or dry deposition.

8. The method of claim 1, wherein the insulating layer is formed to have a thickness of 1,000˜20,000 Å.
